(19) United States
(12) Patent Application Publication
(10) Pub. No.: US 2014/0015523 A1
(43) Pub. Date: Jan. 16, 2014

(54) SENSOR DEVICE, A DETECTOR ARRANGEMENT AND A METHOD FOR DETECTING ARCING

(71) Applicants: Jan Rupf, Dresden (DE); Markus Fischer, Bannewitz OT Gaustritz (DE); Peter Brockhaus, Dresden (DE); Percy Heger, Dresden (DE); Norbert Urbansky, Dresden (DE)

(72) Inventors: Jan Rupf, Dresden (DE); Markus Fischer, Bannewitz OT Gaustritz (DE); Peter Brockhaus, Dresden (DE); Percy Heger, Dresden (DE); Norbert Urbansky, Dresden (DE)

(73) Assignee: INFINEON TECHNOLOGIES AG, Neubiberg (DE)

(21) Appl. No.: 13/545,032

(22) Filed: Jul. 10, 2012

(51) Int. Cl. G01R 33/02

(52) U.S. Cl. 324/244

(57) ABSTRACT

Detecting arcing events in a DC driven semiconductor tool is a challenging process. Various embodiments comprise dedicated sensor devices capable of detecting arcing events by observing the slope of voltage and/or current of a DC power supply line. Using the incorporated interfaces, the sensor could be connected to a computer system. Besides the detector arrangement the unit also provides a method and a corresponding computer program product. Furthermore a simple detection, the unit has the capability of separating the events into its severeness.

### TECHNICAL FIELD

Various embodiments relate generally to a sensor device, a detector arrangement and a method for detecting arcing on a DC driven sputtering system.

### BACKGROUND

Robust sensor devices, detector arrangements and real-time arc detection methods that preclude reconfiguration of presently used DC power supplies and plasma deposition chamber are desirable. Further, it would be desirable for the arc detection devices, arrangements and methods to not introduce new hardware into the standard path for the energy transmission, since this could implement an extended requalification process.

### SUMMARY

In various embodiments, a sensor device is provided including: an input terminal configured to be connected to a first external DC power supply line; an output terminal configured to be connected to a second external DC power supply line; an internal DC power supply line configured to carry a DC current and voltage, the internal DC power supply line being connected to the input terminal and the output terminal; and a sensor configured to detect at least one of the DC current and voltage of the internal DC power supply line by detecting the magnetic effect of the at least one of the DC current and voltage of the internal DC power supply line.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a sensor device according to an embodiment.

FIG. 2 shows a sensor device including a housing according to an embodiment.

FIG. 3 shows a sensor device according to an embodiment.

FIG. 4 shows a detector arrangement according to an embodiment.

FIG. 5 shows a flowchart of a method for detecting arcing according to an embodiment.

### DETAILED DESCRIPTION

The following detailed description refers to the accompanying drawings that show, by way of illustration, specific details and embodiments in which the invention may be practised. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Plasmas are frequently used in the semiconductor industry to process semiconductors wafers, e.g. silicon wafers including at least one integrated circuit. These plasma processes, e.g. physical vapor deposition or sputter deposition, are used for depositing and/or etching thin films of various target materials, e.g. metals like Cu, W or Al, over a substrate, e.g. a silicon wafer. Plasma processes frequently use a plasma deposition chamber in conjunction with the deposition and/or etching process, wherein the plasma deposition chamber encloses the target material and substrate.

Plasma processing includes sputter deposition, which in fact includes direct current (DC) sputtering. In a DC sputtering system, a DC power supply creates an electric field between the target material and the substrate. In an embodiment, the target material may be an anode and the substrate may be a cathode. In another embodiment, the target material may be the cathode and the substrate may be the anode. The plasma deposition chamber may enclose a low pressure inert gas, e.g. argon or nitrogem or the like, within itself. The low pressure inert gas may be ionized by the electric potential set up between the target material and the substrate, thereby creating the plasma.

In DC sputter deposition, the ions of the ionized gas may be used to accelerate the atoms of the target material. In this case, ions of the ionized gas bombard the surface of the target material. The kinetic energy of the ions of the ionized gas may be transferred to the atoms of the target material. Some of the atoms of the target material may then be ejected from the target material. These ejected atoms of the target material then drift across the plasma deposition chamber under the influence of the electric field where they are deposited as a thin film over the substrate.

The word “over” used with regards to the deposited material formed “over” a side or surface of the substrate, may be used herein to mean that the deposited material may be formed “directly on”, e.g. in direct contact with, the implied side or surface of the substrate.

In addition, the word “over” used with regards to the deposited material formed “over” a side or surface of the substrate, may be used herein to mean that the deposited material may be formed “indirectly on” the implied side or surface of the substrate with one or more additional layers being arranged between the implied side or surface of the substrate and the deposited material.

Plasma processes may be unstable by nature. Often, a large, near instantaneous current may be formed within the plasma deposition chamber. The near instantaneouos current typically seeks an electrically conducting channel within the plasma. This phenomenon is commonly known as arcing. Arcing is typically caused by the fact that in addition to the substrate itself, parts of the sputtering system, e.g. the walls of the plasma deposition chamber, may be coated with electrically non-conducting or poorly conducting materials which may become charged up to a breakdown voltage.

Arcing may manifest itself in various forms. Arcing may manifest as hard arcs wherein high power levels may be transferred through the arc, thus causing the target material to be damaged, melted and/or vaporized. Hard arcs may also result in damage to the DC sputtering system, e.g. DC power supply, DC deposition chamber, and to the substrate to be coated. Arcing may also manifest as short arcs wherein high power levels are still transferred through the arc, but these arcs may be self extinguishing and cause less damage to the DC sputtering system. Arcing may also manifest as micro arcs. Micro arcs also tend to extinguish themselves and typically occur over time scales of a few microseconds or less, e.g. 20 microseconds, 15 microseconds, 10 microseconds, 5 microseconds or 2 microseconds. Micro arcs may also be distinguished from hard arcs in the magnitude of the current spike, wherein micro arcs cause minor spiking. Although minor spiking may not lead to a major current breakdown, minor spiking, and hence micro arcs, may cause defect density issues on the substrate a-s well as wafer scrap. In addition, micro arcs may be amplified and may lead to a cascading effect which can result in either one of a short arc or a hard arc. Accordingly, there is a need to detect at least micro arcing in plasma processes, e.g. a DC sputtering system.

Possible methods for detecting at least micro arcs in a DC sputtering system may include external sensors (voltage and/or current), such as sensors that measure directely the physical value or indirect like meassuring the fields. (This, for example, could include a clamp-on ammeter working with methods as methods like coils wrapped around the DC power supply line and hall detectors). However, any one of these methods may result in low signal to noise ratio (SNR), thus necessitating filtering of the measured data from the background noise, wherein background noise may include effects of electrical or magnetic shielding as well as effects of scatter signals.

Additional possibilities for detecting arcing in a DC sputtering system include observing the floating and/or bias potential of the DC sputtering system, or by observing the plasma emission optically using optical probes. Since there may be no direct access to conductive surfaces exposed to the plasma, an observation of the voltage within the plasma deposition chamber may not possible. A direct access for an optical probe may not possible as well. Further, other metrics such as reflected power and VI-probes may not be possible in the case of DC sputtering systems.

Since arcing in a DC plasma process may be recognized by at least one of a voltage drop and a current rise in the DC power supply to the plasma deposition chamber, an arc discharge within the plasma deposition chamber may be detected by sensing at least one of the DC current and voltage of the DC power supply. Further, a micro arc discharge in a DC sputtering system may be detected by high data rate acquisition of the at least one of the DC current and voltage of the DC power supply. Further, the data acquisition of the at least one of the DC current and voltage of the DC power supply must be sensed without having to disrupt or open the current path from the DC power supply to the plasma deposition chamber. Stated differently, the data acquisition must be effected by keeping the physical path between the DC power supply and the DC sputtering chamber unperturbed and untouched. This may ensure an accurate sensing of the at least one of the DC current and voltage of the DC power supply. Accordingly, this may enable effective and accurate detection of arcing within the plasma deposition chamber.

Detecting arcing events in a DC driven semiconductor tool is a challenging process. Various embodiments comprise dedicated sensor devices capable of detecting arcing events by observing the slope of voltage and/or current of a DC power supply line. Using the incorporated interfaces, the sensor could be connected to a computer system. Besides the detector arrangement the unit also provides a method and a corresponding computer program product. Furthermore a simple detection, the unit has the capability of separating the events into its severeness.

Consequently, various exemplary embodiments provide a sensor device to detect (e.g. contactlessly detect) at least one of the DC current and voltage of a DC power supply. The word “exemplary” is used herein to mean “serving as an example, instance, or illustration”. Any embodiment or design described herein as “exemplary” is not necessarily to be construed as preferred or advantageous over other embodiments or designs.

Various exemplary embodiments provide a detector arrangement for detecting arcing.

Various exemplary embodiments provide a method for detecting arcing.

Various exemplary embodiments provide a device configured to detect arcing.

Various exemplary embodiments provide a computer program product, which, when executed by a computer, makes the computer perform a method for detecting arcing.

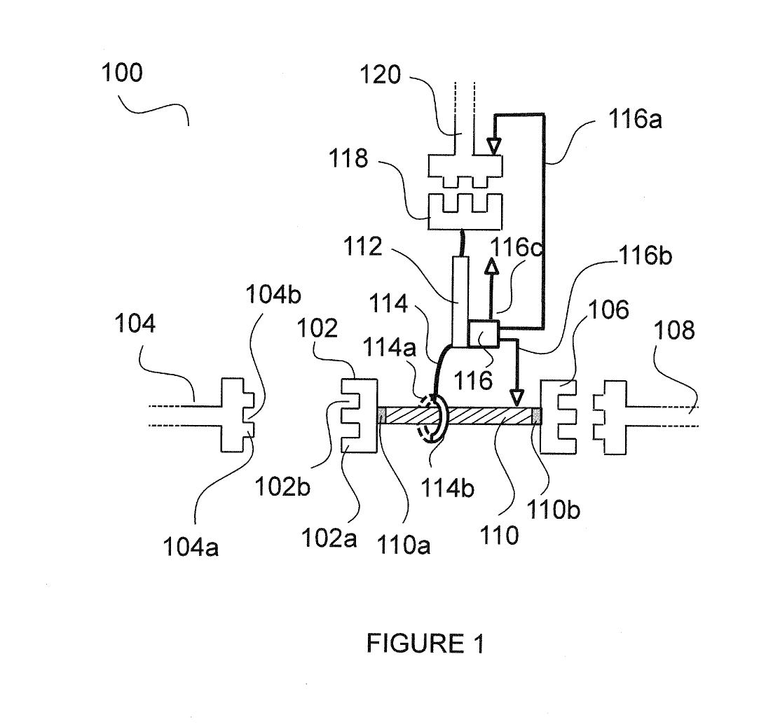

FIG. 1 shows a sensor device 100 according to an embodiment. In an embodiment, the sensor device 100 includes an input terminal 102 configured to be connected to a first external DC power supply line 104. In an embodiment, the input terminal may include a plurality of jacks and/or sockets and/or connectors 102a, 102b such that the input terminal 102 may be compatible to a plurality of jacks and/or sockets and/or connectors 104a, 104b of the first external DC power supply line 104. For example, the first external DC power supply 104 line may include any one of a cylindrical connector, a snap-and-lock DC power connector, a Molex connector, an IEC 60906-3:1994 connector, a Tamiya connector, a Deans connector, a JST-RCY connector, an Inverter tab or lug, an Anderson powerpole connector, a High Voltage-DC rated connector, an SAE connector, an ISO 4165 connector, or other variants of DC connectors. Accordingly, in an embodiment, the input terminal 102 includes the required number of jacks and/or sockets and/or connectors 102a, 102b, wherein each jack and/or socket and/or connector 102a, 102b is further arranged in a required configuration such that the input terminal 102 may be securely connected to the first external DC power supply line 104.

In an embodiment, the sensor device 100 may include an output terminal 106 configured to be connected to a second external DC power supply line 108. The further features described above with reference to the input terminal 102 and the first external DC power supply line 104 are equally applicable, and hereby restated, in respect of the output terminal 106 and the second external DC power supply line 108, respectively.

In an embodiment, the sensor device 100 may include an internal DC power supply line 110, 110a, 110b configured to carry a DC current and voltage. The word “carry” is used herein to mean “conduct”. Accordingly, in an embodiment, an internal DC power supply line 110, 110a, 110b may be configured to conduct a DC current and voltage. In an embodiment, a first end 110a of the internal DC power supply line 110 may be configured to connect to the input terminal 102 and a second end 110b of the internal DC power supply line 110 may be configured to connect to the output terminal 106. Accordingly, in an embodiment, the internal DC power supply line 110, 110a, 110b may provide an electrical conduction path between the input terminal 102 and the output terminal 106.

In an embodiment, the sensor device 100 may include a sensor 112 configured to detect (e.g. contactlessly detect) at least one of the DC current and voltage-of the internal DC power supply line 110, 110a, 110b by detecting the magnetic effect of the at least one of the DC current and voltage of the internal DC power supply line 110, 110a, 110b.

In an embodiment, the sensor 112 may be further configured to contactlessly detect at least one of the DC current and voltage of the internal DC power supply line 110, 110a, 110b. Stated differently, the sensor 112 may be further configured to detect at least one of the DC current and voltage of the internal DC power supply line 110, 110a, 110b without making physical contact with the internal DC power supply line 110, 110a, 110b, i.e. contactless detection. Accordingly, at least one of the DC current and voltage of the internal DC power supply line 110, 110a, 110b may be detected by keeping the electrical conduction path provided by the internal DC power supply line 110, 110a, 110b unperturbed and/or untouched. In an embodiment, the contactless detection of at least one of the DC current and voltage may be effected by detecting the magnetic effect of the at least one of the DC current and voltage of the internal DC power supply line 110, 110a, 110b.

In an embodiment, the sensor 112 may include a flux gate sensor 114, 114a, 114b but others as well to detect the current conducted on the internal DC power supply line.

The flux gate sensor 114, 114a, 114b may include a sense coil surrounding a central core 114a 114b, wherein the central core includes two core halves 114a, 114b. Each core half 114a, 114b of the flux gate sensor 114 may include a drive coil, wherein the drive coil may be wound around a magnetically permeable or suscepticle core material, e.g. iron, iron oxide, or the like. In an embodiment, a current, e.g. a constant DC current or a pulsed DC current, may be applied to the drive winding of each core half 114a, 114b. In an embodiment, the current of each core half 114a, 114b of the flux gate sensor 114 may be applied as opposite polarities. Illustratively, this means that if the instantaneous current applied to the drive winding of the first core half 114a is +10 A, the instantaneous current applied to the drive winding of second core half 114b may be −10 A. In another illustrative example, if the instantaneous current applied to the drive winding of the first core half 114a is −22.2 A, the instantaneous current applied to the drive winding of second core half 114b may be +22.2 A. The instantaneous current values used in the illustrative examples are merely examples and are meant to illustrate the current of each core half 114a, 114b of the flux gate sensor 114 being of opposite polarities. They are not intended to be limiting.

In an embodiment, the two core halves 114a, 114b may be carefully matched in terms of number of drive coil windings, distance between consecutive windings, or in terms of other factors that may affect the magnetic saturation of each core half 114a, 114b. In the absence of an external magnetic field, the flux in one core half 114a substantially cancels the flux in the other 114b if the two core halves 114a, 114b are substantially matched. In this context, two core halves 114a, 114b that are substantially matched may be termed as having zero alignment. Accordingly, the sense coil of a flux gate sensor 114, 114a, 114b having zero alignment may sense substantially zero total flux in the absence of an external magnetic field. Accordingly, at least one of the current and the voltage in the sense coil is substantially zero in the absence of an external magnetic field.

If an external magnetic field is present, such as when a DC current carrying conductor passes near or through the flux gate sensor 114a, 114b, the external magnetic field may, at a given instance in time, aid the flux in one core half 114a and oppose the flux in the other core half 114b. This may cause a net flux imbalance between the two core halves 114a, 114b such that their respective fluxes no longer cancel one another. Consequently, a current may be induced in the sense coil. The current induced in the sense coil may depend on both the magnitude of the external magnetic field and the polarity of the external magnetic field. Likewise, the magnitude of the external magnetic field may be proportional to the current conducted by the DC current carrying conductor passing near or through the flux gate sensor 114, 114a, 114b. Accordingly, the DC current of the conductor passing near or through the flux gate sensor 114, 114a, 114b may be detected by detecting the magnetic effect of the DC current carrying conductor. Further, in an embodiment the DC voltage of the current carrying conductor may be determined.

In an embodiment, the above-mentioned DC current carrying conductor may be the aforementioned internal DC power supply line 110, 110a, 110b. Accordingly, in an embodiment, the sensor 112 may be configured to detect at least one of the DC current and voltage of the internal DC power supply line 110, 110a, 110b by detecting the magnetic effect of the at least one of the DC current and voltage of the internal DC power supply line 110, 110a, 110b.

In an aforementioned embodiment, the sensor 112 may include a flux gate sensor 114, 114a, 114b. Accordingly, in an embodiment, the internal DC power supply line 110, 110a, 110b may pass through the flux gate sensor 114, 114a, 114b so as to enable the flux gate sensor 114, 114a, 114b to detect at least one of the DC current and voltage of the internal DC power supply line 110, 110a, 110b by detecting the magnetic effect of the at least one of the DC current and voltage of the internal DC power supply line 110, 110a, 110b. In an embodiment, the flux gate sensor 114, 114a, 114b may include a current clamp. Accordingly, in an embodiment, the internal DC power supply line 110, 110a, 110b may pass through a current clamp 114, 114a, 114b.

In an embodiment, the sensor 100 may include a differential sensor probe 116. In an embodiment, the differential sensor probe 116 may measure at least the voltage between a first lead 116a and a second lead 116b. In an embodiment, lead 116c may be the output terminal for the measured voltage. This lead 116c may be isolated from the measurement pins 116a, 116b as these will conduct high voltages.

In an embodiment, the first lead 116a and the second lead 116b of the differential sensor probe 116 may be galvanically separated from the output terminal 116c for the measured voltage. Galvanic separation is a principle of isolating functional sections of an electrical system from one another to prevent current flow between or among the functional sections. Galvanic separation may be used where two or more electric circuits must communicate electrically, but each of their ground or reference potentials may be at a different voltage, as in the case of the differential sensor probe 116. Galvanic separation may also be used for environmental, safety, and health (ESH) concerns to prevent accidental current from reaching ground through a human body. Nonetheless, electrical energy may still be exchanged between the first lead 116a and the second lead 116b of the differential sensor probe 116 by other means, e.g. by capacitance, inductance, or electromagnetic waves. Accordingly, in an embodiment, the sensor 112, which may include a differential sensor probe 116, may be configured to detect at least one of the DC current and voltage of the internal DC power supply line 110, 110a, 110b by detecting the magnetic effect of the at least one of the DC current and voltage of the internal DC power supply line 110, 110a, 110b.

In an embodiment, the voltage between the first lead 116a and the second lead 116b may be measured with respect to the first lead 116a. In an embodiment, the voltage between the first lead 116a and the second lead 116b may be measured with respect to the second lead 116b. Illustratively, if the first lead 116a is at 100 V and the second lead 116b is at 200 V, the differential sensor probe 116 may give reading of 100 V if measurements are made with respect to the first lead 116a. In another illustrative example, if the first lead 116a is at 100 V and the second lead 116b is at 200 V, the differential sensor probe 116 may give reading of −100 V if measurements are made with respect to the second lead 116b. Accordingly, in an embodiment, the differential sensor probe 116 may be used to measure negative potentials as well as positive potentials. Consequently, the differential sensor probe 116 may measure at least a voltage across circuit elements without the constraint of a needing a common ground or a common reference potential. Herein the words “potential” and “voltage” are used interchangeably. Further, the voltage values used in the illustrative examples are merely illustrative and are not intended to be limiting.

In an embodiment, the sensor 112, which may include at least one of a differential sensor probe 116 and a flux gate sensor 114, 114a, 114b, may require at least one power source. In respect of the sensor 112 including a differential sensor probe 116, the power source may provide a reference voltage to either one of the first lead 116a or the second lead 116b of the differential sensor probe 116. In respect of the sensor 112 including a flux gate sensor 114, 114a, 114b having zero alignment, the power source may be configured to induce flux in each of the two core halves 114a, 114b of the flux gate sensor 114, 114a, 114b. Consequently, in an embodiment, the sensor device 100 may further include a sensor-power terminal 118 configured to be connected to a third external DC power supply line 120. The further features described above with reference to the input terminal 102 of the sensor device 100 and the first external DC power supply line 104 are equally applicable, and hereby restated, in respect of the sensor-power terminal 118 and the third external DC power supply line 120, respectively.

In an embodiment, the sensor-power terminal may be configured to provide power to at least one of the differential sensor probe 116 and the flux gate sensor 114, 114a, 114b of the sensor 112.

In an embodiment, the sensor 112, which may include at least one of a differential sensor probe 116 and a flux gate sensor 114, 114a, 114b, may be further configured to detect the at least one of the DC current and voltage of the internal DC power supply line 110, 110a, 110b with a temporal resolution of up to 10 microseconds. Accordingly, the at least one of the DC current and voltage of the internal DC power supply line 110, 110a, 110b may be sampled, for example, about every 10 microseconds, or about every 8 microseconds, or about every 7 microseconds, or about every 6 microseconds, or about every 5 microseconds, or about every 4 microseconds, or about every 3 microseconds, or about every 2 microseconds, or about every 1 microsecond. Consequently, in an embodiment, the sensor 112 may be further configured to sense the DC current with a sense frequency of about 1 MHz. Accordingly, in an embodiment, a micro arc discharge in a DC sputtering system may be detected by high data rate acquisition, e.g. with a sense frequency of about 1 MHz, of the at least one of the DC current and voltage of the DC power supply.

In an embodiment, the sensor 112, which may include at least one of a differential sensor probe 116 and a flux gate sensor 114, 114a, 114b, may be further configured to detect the at least one of the DC current and voltage of the internal DC power supply line 110, 110a, 110b with a temporal resolution of up to 1 microseconds. Accordingly, the at least one of the DC current and voltage of the internal DC power supply line 110, 110a, 110b may be sampled, for example, about every 1 microsecond, or about every 0.8 microseconds, or about every 0.6 microseconds, or about every 0.4 microseconds, or about every 0.2 microseconds.

In an embodiment, the sensor 112 of the sensor device 100 may be further configured to detect a peak current of up to 200 A. Consequently, the sensor 112 may be configured to detect the DC current of the internal DC power supply line 110, 110a, 110b, wherein the peak current of the internal DC power supply line 110, 110a, 110b may be in the range of about 0 A to about 200 A, or in the range of about 0 A to about 150 A, or in the range of about 0 A to about 100 A, or in the range of about 0 A to about 80 A, or in the range of about 0 A to about 60 A, or in the range of about 0 A to about 40 A, or in the range of about 0 A to about 20 A, or in the range of about 0 A to about 10 A, or in the range of about 0 A to about 5 A, or in the range of about 0 A to about 3 A, or in the range of about 0 A to about 1 A. Accordingly, a spike in the current amplitude when arching occurs in the plasma deposition chamber may be detected by the sensor 112 of the sensor device 100.

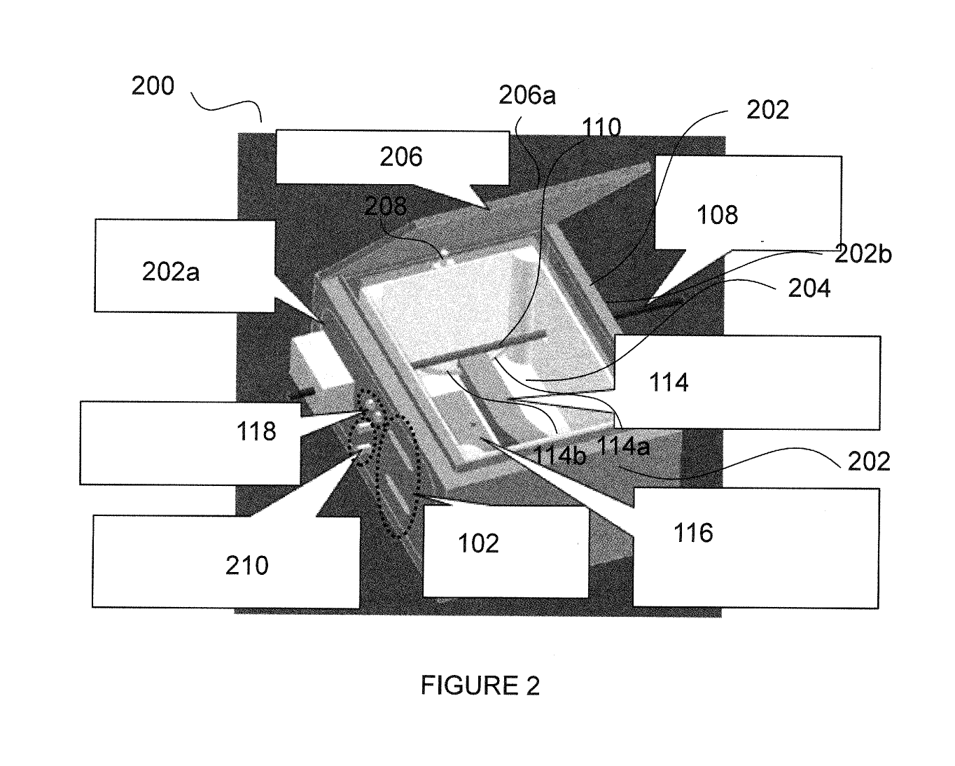

FIG. 2 shows a sensor device 200 including a housing 202 according to an embodiment.

In an embodiment, the sensor device may further include a housing 202. In an embodiment, the housing 202 may include a hollow cavity 204. The housing 202 may be made of any material that meets ESH (Environment, Safety and Health) requirements, e.g. any non-conducting material or any combination thereof, or any poorly conducting material or any combination thereof, or any combination of at least one poorly conducing material and at least one non-conducting material. In an embodiment, the internal DC power supply line 110 and the sensor 112, which may include at least one of a differential sensor probe 116 and a flux gate sensor 114, 114a, 114b, are contained within the housing 202, namely within the hollow cavity 204 of the housing 202. In an embodiment, the input terminal 102, the output terminal (not shown in FIG. 2) and the sensor-power terminal 118 are mounted on at least one external face 202a of the housing 202. For example, in an embodiment where the housing 202 is a hollow cuboid with a hollow cavity 202a, the input terminal 102 may be mounted on a first external face 202a of the housing 202, the output terminal (not shown in FIG. 2) may be mounted on a second external face 202b of the housing 202, and the sensor-power terminal 118 may be mounted on the first external face 202a of the housing 202. Alternatively, in another embodiment, the input terminal 102, the output terminal 106 and the sensor-power terminal 118 may be mounted on one and the same external face of the housing 202.

In an embodiment, the housing 202 may include at least one interlocking cover 206. The interlocking cover 206 may be configured to be in an open position or a closed position. In an embodiment, the at least one interlocking cover 206 may include an external face 206a of the housing 202.

In an embodiment, the housing 202 may further include a interlock switch 208, wherein the interlock switch 208 may be configured to be in an OFF position when the at least one interlocking cover 206 is in the open position, as is shown in FIG. 2. In an embodiment, the interlock switch 208 may be configured to be in an ON position when the at least one interlocking cover 206 is in the closed position. In an embodiment, the sensor device 200 may be inoperable when the at least one interlocking cover 206 is opened. In an embodiment, power supply to the sensor delivered through the sensor-power terminal 118 (the sensor including at least one of a differential sensor probe 116 and a flux gate sensor 114, 114a, 114b) may be configured to be disrupted when the interlock switch 208 is in the OFF position, namely when at least one interlocking face 206, 202a is opened, as is shown in FIG. 2 in respect of interlocking face 206. Similarly, the input terminal 102 and/or the output terminal (not shown in FIG. 2) may be configured to be electrically or conductively disconnected from the first external DC power supply line 104 (not shown in FIG. 2) and the second external DC power supply line 108, respectively, when at least one interlocking face 206, 202a is opened. In an embodiment, the interlock switch 208 may be included in order for the sensor device 200 to comply with ESH requirements.

In an embodiment, the sensor device 200 may further include at least one BNC terminal 210 configured to connect to at least one BNC cable (not shown in FIG. 2). In an embodiment, the at least one BNC terminal 210 may be mounted on at least one external face of the housing 202a. In an embodiment, the at least one of the detected DC current and voltage of the internal DC power supply line 110 is conducted through a current and/or voltage path to the BNC cable (not shown in FIG. 2) through the BNC terminal 210. In an embodiment, the BNC cable (not shown in FIG. 2) may be connected to an oscilloscope (not shown in FIG. 2) or a display device (not shown in FIG. 2). In an embodiment the BNC cable (not shown in FIG. 2) may be further connected to an advanced process control (APC) hardware interface (not shown in FIG. 2).

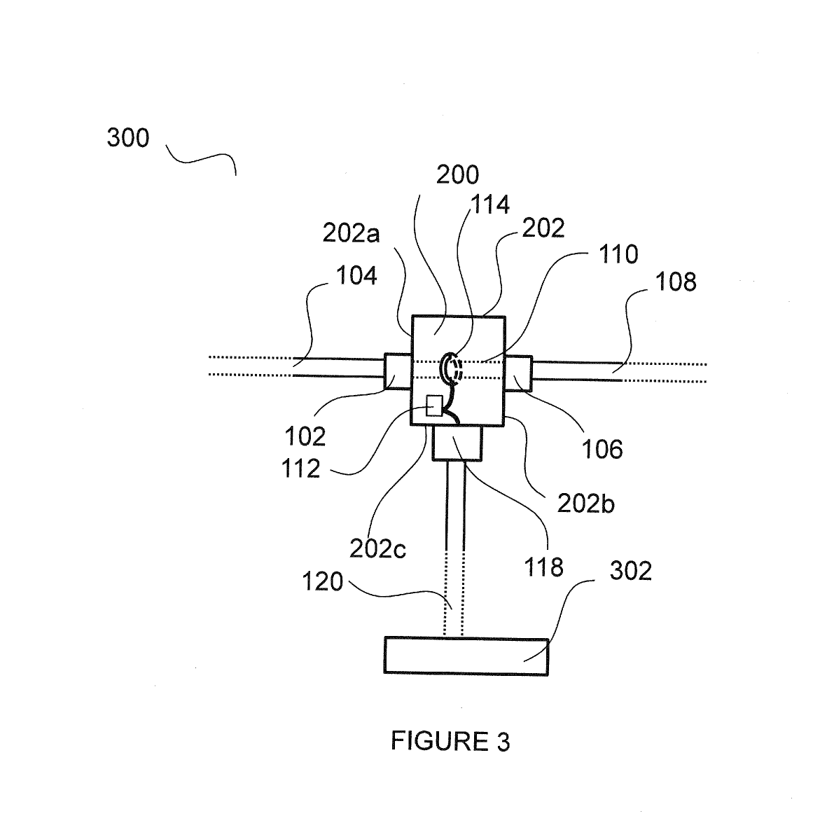

FIG. 3 shows a sensor device according to an embodiment. In an embodiment, the sensor device 200 may further include a first external DC power supply line 104, a second external DC power supply line 108, and a third external DC power supply line 120.

In an embodiment, the sensor device 200 may be connected to the first external DC power supply line 104 through the input terminal 102 which may be mounted on an external face 202a of the housing 202. In an embodiment, the input terminal 102 includes the required number of jacks and/or sockets and/or connectors, wherein each jack and/or socket and/or connector is further arranged in a required configuration such that the first external DC power supply line 104 may be securely and properly connected to the input terminal 102. Consequently, in an embodiment, the internal DC power supply line 110 contained within the housing 202 may be further configured to connect to the first external DC power supply line 104 through the input terminal 102 mounted on an external face 202a of the housing 202.

In an embodiment, the sensor device 200 may be connected to the second external DC power supply line 108 through the output terminal 106 which is mounted on an external face 202b of the housing 202. In an embodiment, the output terminal 106 includes the required number of jacks and/or sockets and/or connectors, wherein each jack and/or socket and/or connector is further arranged in a required configuration such that the second external DC power supply line 108 may be securely and properly connected to the output terminal 106. Consequently, in an embodiment, the internal DC power supply line 110 contained within the housing 202 may be further configured to connect to the second external DC power supply line 108 through the output terminal 106 mounted on an external face 202b of the housing 202.

As a further consequence, in an embodiment, the first external DC power supply line 104, the second external DC power supply line 108 and the internal DC power supply line 110 may be electrically connected to one another. In an embodiment, at least one of the first external DC power supply line 104, the second external DC power supply line 108 and the internal DC power supply line 110 may be configured to carry a DC current of up to 60 A, e.g. a DC current in the range of about 0 A to about 60 A, or in the range of about 0 A to about 40 A, or in the range of about 0 A to about 20 A, or in the range of about 0 A to about 10 A, or in the range of about 0 A to about 5 Å.

In an embodiment, at least one of the first external DC power supply line 104, the second external DC power supply line 108 and the internal DC power supply line 110 may be configured to carry a DC voltage up to 2.5 kV, e.g. a DC voltage in the range of about 0 kV to about 2.5 kV, or in the range of about 0 kV to about 2 kV, or in the range of about 0 kV to about 1.5 kV, or in the range of about 0 kV to about 1 kV.

In an embodiment, at least one of the first external DC power supply line 104, the second external DC power supply line 108 and the internal DC power supply line 110 may be configured to carry a DC voltage up to 1 kV, e.g. a DC voltage in the range of about 0 kV to about 1 kV, or in the range of about 0 kV to about 0.8 kV, or in the range of about 0 kV to about 0.6 kV, or in the range of about 0 kV to about 0.4 kV, or in the range of about 0 kV to about 0.2 kV, or in the range of about 0 kV to about 0.1 kV.

In an embodiment, the sensor device 200 may be connected to the third external DC power supply line 120 through the sensor-power terminal 118 which may be mounted on an external face 202c of the housing 202. In an embodiment, the sensor-power terminal 118 may include the required number of jacks and/or sockets and/or connectors, wherein each jack and/or socket and/or connector may be further arranged in a required configuration such that the third external DC power supply line 120 may be securely and properly connected to the sensor-power terminal 118.

In an embodiment, the third external DC power supply line 120 may be configured to be connected to a power supply 302. In an embodiment, the Sensors DC power supply line 120 may be configured to supply a voltage of up to 12 V to the sensor, e.g. a voltage in the range of about 0 V to about 12 V, or in the range of about 0 V to about 10 V, or in the range of about 0 V to about 8 V, or in the range of about 0 V to about 6 V, or in the range of about 0 V to about 4 V, in the range of about 0 V to about 2 V. Accordingly, in an embodiment, the sensor 112 (which may include flux sensor 114) contained within the housing 202 may be configured to be connected to the third external DC power supply line 120 through the sensor-power terminal 118 mounted on an external face 202c of the housing 202.

In an embodiment, the third external DC power supply line may be configured to supply a voltage of up to 9 V to the sensor 112 (which may include flux sensor 114) contained within the housing 202, e.g. a voltage in the range of about 0 V to about 9 V, or in the range of about 0 V to about 7 V, or in the range of about 0 V to about 5 V, or in the range of about 0 V to about 3 V, or in the range of about 0 V to about 1 V. Accordingly, in an embodiment, the sensor 112 (which may include flux sensor 114) contained within the housing 202 may be configured to be connected to the third external DC power supply line 120 through the sensor-power terminal 118 mounted on an external face 202c of the housing 202.

Various exemplary embodiments provide a detector arrangement. The word “exemplary” is used herein to mean “serving as an example, instance, or illustration”. Any embodiment or design described herein as “exemplary” is not necessarily to be construed as preferred or advantageous over other embodiments or designs.

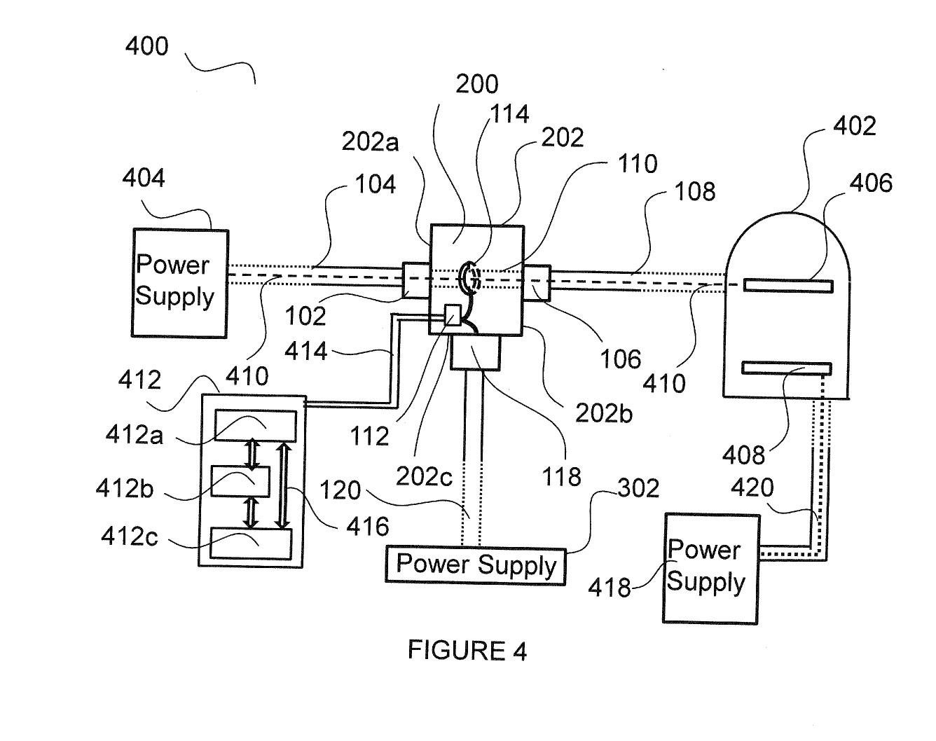

FIG. 4 shows a detector arrangement 400 according to an embodiment. In an embodiment, the detector arrangement 400 may include an input terminal 102, an output terminal 106, an internal DC power supply line 110, a sensor 112 (which may include a flux sensor 114) and a housing 202. In an embodiment, the input terminal 102 may be configured to be connected to a first external DC power supply line 104. In an embodiment, the output terminal 106 may be configured to be connected to a second external DC power supply line 108. In an embodiment, the internal DC power supply line 110 may be configured to carry a DC current and voltage. In an embodiment, the internal DC power supply line 110 may be electrically connected to the input terminal 102 and the output terminal 108. In an embodiment, the sensor 112 (which may include flux sensor 114) may be configured to detect at least one of the DC current and voltage of the internal DC power supply line 110 by detecting the magnetic effect of the at least one of the DC current and voltage of the internal DC power supply line 110. In an embodiment, the housing 202 may be configured to contain the internal DC power supply line 110 and the sensor 112. In an embodiment, the input terminal 102 and the output terminal 106 may be mounted on at least one external face 202a, 202b of the housing.

The further features described above with reference to each of the input terminal 102, the output terminal 106, the internal DC power supply line 110, the sensor 112 and the housing 202 of any one of the sensor devices 100, 200, 300 are equally applicable, and hereby restated, in respect of the input terminal 102, the output terminal 106, the internal DC power supply line 110, the sensor 112 and the housing 202 of the detector arrangement 400, respectively.

In an embodiment, the detector arrangement 400 may include a first external DC power supply line 104 and a second external DC power supply line 108. In an embodiment, any one of the first external DC power supply line 104 or the second external DC power supply line 108 of the detector arrangement 400 may be further connected to a high-voltage DC power supply 404 and a plasma deposition chamber 402, wherein the plasma deposition chamber 402 encloses a target material 406 and substrate 408. In an embodiment, at least one of a DC current and voltage 410 may be supplied by the high-voltage DC power supply 404 to the plasma deposition chamber 402. In an embodiment, the at least one of the DC current and voltage 410 may be supplied by the high-voltage DC power supply 404 to the target material 406 enclosed within the plasma deposition chamber 402. In an embodiment, a high voltage DC power supply 418 may be configured to supply at least one of a DC current and voltage 420 to the substrate material 408 enclosed within the plasma deposition chamber 402. In an embodiment, at least one of the DC current and voltage 420 supplied by the high-voltage DC power supply 418 to the substrate material 408 may be different from at least one of the DC current and voltage 410 supplied by the high-voltage DC power supply 404 to the target material 406.

In an embodiment, the first external DC power supply line 104 may be connected to the high-voltage DC power supply 404 and the second external DC power supply line 108 may be connected to the plasma deposition chamber 402. Consequently, in an embodiment, the detector arrangement 400 may be configured to detect at least one of the DC current and voltage 410 supplied to the plasma deposition chamber 402 by detecting the magnetic effect of the at least one of the DC current and voltage of the internal DC power supply line 110.

In an embodiment, the detector arrangement 400 may further include a device 412 configured to detect arcing in the plasma deposition chamber 402 using at least the detected magnetic effect of the at least one of the DC current and voltage 410 of the internal DC power supply line 110. In an embodiment, the device 412 may be configured to receive at least one least one of the DC current and voltage 410 of the internal DC power supply line 110, detected by the sensor 112 via a current and/or voltage path 414 between the sensor 112 and the device 412.

In an embodiment, the device 412 may include a first circuit 412a configured to process the DC current 410 of the internal DC power supply line 110 sensed by the sensor 112. In an embodiment, the device 412 may include a second circuit 412b configured to process the DC voltage 410 of the internal DC power supply line 110 sensed by the sensor 112. In an embodiment, the first circuit 412a and the second circuit 412b may be one and the same circuit. In an embodiment, at least one of the first circuit 412a and the second circuit 412b may be configured to process at least one of the DC voltage and current of the internal DC power supply line plotting at least one of the detected DC current and voltage against time.

In an embodiment, the device 412 may include a third circuit 412c configured to detect if arcing has occurred in the plasma deposition chamber 402. In an embodiment, the first circuit 412a, the second circuit 412b, and the third circuit 412c may be communicatively coupled 416 to one another. In an embodiment, the third circuit 412c may be configured to generate at least one metric corresponding to a pattern of the plot of the least one of the detected DC current and voltage against time.

In an embodiment, the third circuit 412c may be further configured to compare the determined at least one metric to at least one threshold. In an embodiment, the third circuit 412c may be further configured to determine if arcing has occurred in the plasma deposition chamber 402 using the result of the comparison.

It is noted herein that any other kind of implementation of the respective functions of any one of the first circuit 412a, the second circuit 412b and the third circuit 412b may also be understood as a “circuit” in accordance with an alternative embodiment. Accordingly, the use of three constituent circuits 412a, 412b, 412c is not meant to be limiting, and any functional equivalence may also be embraced.

Further, as used herein, a “circuit” may be understood as any kind of a logic implementing entity, which may be special purpose circuitry or a processor executing software stored in a memory, firmware, or any combination thereof. Thus, in an embodiment, a “circuit” may be a hard-wired logic circuit or a programmable logic circuit such as a programmable processor, e.g. a microprocessor (e.g. a Complex Instruction Set Computer (CISC) processor or a Reduced Instruction Set Computer (RISC) processor). A “circuit” may also be a processor executing software, e.g. any kind of computer program, e.g. a computer program using a virtual machine code such as e.g. Java. Different circuits can thus also be implemented by the same component, e.g. by a processor executing two different programs.

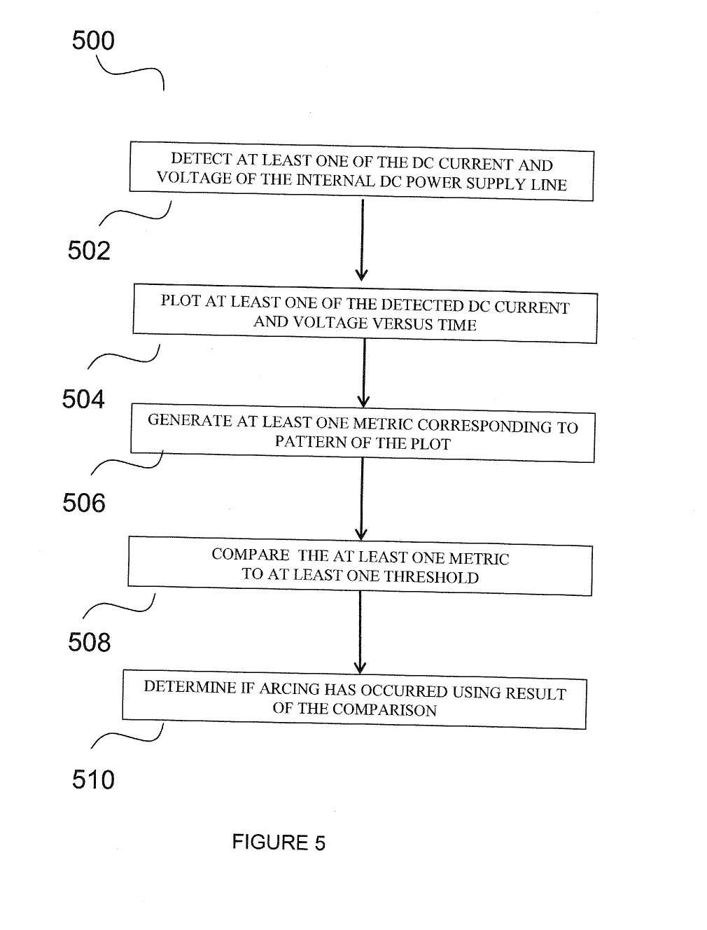

Various embodiments provide a method for detecting arcing. FIG. 5 shows a flowchart of a method 500 for detecting arcing according to an embodiment. In an embodiment, the method may commence with detecting at least one of the DC current and voltage of the internal DC power supply line (502), wherein the internal DC power supply line corresponds to the internal DC power supply line 110, 110a, 110b of any one embodiment of the sensor device 100, 200, 300, or of the detector arrangement 400.

In an embodiment, at least one of the detected DC current and voltage may be plotted against time (504). Accordingly, in an embodiment, plotting at least one of the detected DC current and voltage against time may yield a time history of at least one of the DC current and voltage of the internal DC power supply line. The time resolution, namely, the difference between consecutive points on the time axis may depend on how often the sensor 112 (which may include at least one of a differential sensor probe 116 and a flux gate sensor 114) detects the at least one of the DC current and voltage of the internal DC power supply line.

Accordingly, in an embodiment, the at least one of the detected DC current and voltage may be plotted against time (504) about every 10 microseconds, or about every 8 microseconds, or about every 7 microseconds, or about every 6 microseconds, or about every 5 microseconds, or about every 4 microseconds, or about every 3 microseconds, or about every 2 microseconds, or about every 1 microsecond, or about every 0.8 microseconds, or about every 0.6 microseconds, or about every 0.4 microseconds, or about every 0.2 microseconds.

In an embodiment, the method 500 may include generating at least one metric corresponding to a pattern of the plot (506), i.e. pattern of the time history of at least one of the detected DC current and voltage. In an embodiment, the at least one metric may include at least one coefficient of a linear regression, or a residual analysis of a linear regression, kurtosis, skewness, gradients, or the like.

In an embodiment, the method 500 may include comparing the at least one metric determined in 506 to at least one threshold (508). In an embodiment, the at least one threshold may be empirically determined and/or may be adjusted while the at least one DC current and voltage is detected, namely, the at least one threshold may be an adaptive threshold. In another embodiment, the at least one threshold may be a fixed constant.

In an embodiment, the method 500 may include determining if arcing has occurred using the result of the comparison (510). In an embodiment, arcing may be determined to have occurred if the at least one metric is larger than the at least one threshold. In an embodiment, arcing may be determined to have occurred if the at least one metric is smaller than the at least one threshold.

Various embodiments provide a computer program product, which, when executed by a computer, makes the computer perform a method for detecting arcing, the method including at least one of the following: detecting at least one of the DC current and voltage of the internal DC power supply line; plotting at least one of the detected DC current and voltage against time; generating at least one metric corresponding to a pattern of the plot; comparing the determined at least one metric to at least one threshold; and determining if arcing has occurred using the result of the comparison. The further features described above with reference to the method 500 are equally applicable, and hereby restated, in respect of the methods of the computer program product.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A sensor device, comprising:
an input terminal configured to be connected to a first external DC power supply line;
an output terminal configured to be connected to a second external DC power supply line;
an internal DC power supply line configured to carry a DC current and voltage,
the internal DC power supply line being connected to the input terminal and the output terminal; and
a sensor configured to detect at least one of the DC current and voltage of the internal DC power supply line by detecting the magnetic effect of the at least one of the DC current and voltage of the internal DC power supply line.

2. The sensor device according to claim 1, wherein the sensor is further configured to contactlessly detect at least one of the DC current and voltage of the internal DC power supply line.

3. The sensor device according to claim 1,
wherein the sensor comprises a differential sensor probe.

4. The sensor device according to claim 3,
wherein the differential sensor probe comprises a first lead and a second lead, the first lead and the second lead being galvanically separated from an output of the differential sensor probe.

5. The sensor device according to claim 1,
wherein the sensor comprises a flux gate sensor.

6. The sensor device according to claim 5,
wherein the flux gate sensor comprises a current clamp.

7. The sensor device according to claim 6,
wherein the internal DC power supply line passes through the current clamp.

8. The sensor device according to claim 5,
wherein the flux gate sensor is configured to have zero alignment.

9. The sensor device according to claim 1,
wherein the sensor is further configured to detect the at least one of the DC current and voltage of the internal DC power supply line with a temporal resolution of up to 10 microseconds.

10. The sensor device according to claim 1, further comprising:
a sensor-power terminal configured to be connected to a third external DC power supply line.

11. The sensor device according to claim 10, further comprising:
a first external DC power supply line, a second external DC power supply line, and a third external DC power supply line;
wherein the sensor device is connected to the first external DC power supply line through the input terminal, wherein the sensor device is connected to the second external DC power supply line through the output terminal, and wherein the sensor device is connected to the third external DC power supply line through the sensor-power terminal.

12. The sensor device according to claim 11,
wherein at least one of the first external DC power supply line, the second external DC power supply line and the internal DC power supply line is configured to carry a DC current of up to 60 A.

13. The sensor device according to claim 11,
wherein at least one of the first external DC power supply line, the second external DC power supply line and the internal DC power supply line is configured to carry a DC voltage up to 2.5 kV.

14. A detector arrangement, comprising:
an input terminal configured to be connected to a first external DC power supply line;
an output terminal configured to be connected to a second external DC power supply line;
an internal DC power supply line configured to carry a DC current and voltage, the internal DC power supply line being connected to the input terminal and the output terminal;
a sensor configured to detect at least one of the DC current and voltage of the internal DC power supply line by detecting the magnetic effect of the at least one of the DC current and voltage of the internal DC power supply line;
a housing configured to contain the internal DC power supply line and the sensor, the input terminal and the output terminal mounted on at least one external face of the housing.

15. The detector arrangement according to claim 14, wherein the sensor is further configured to detect at least one of the DC current and voltage of the internal DC power supply line.

16. The detector arrangement according to claim 14,
wherein the sensor comprises a differential sensor probe.

17. The detector arrangement according to claim 16,
wherein the differential sensor probe comprises an input lead and an output lead, the input lead and the output lead being galvanically separated from each other.

18. The detector arrangement according to claim 14,
wherein the sensor comprises a flux gate sensor.

19. The detector arrangement according to claim 18,
wherein the flux gate sensor comprises a current clamp.

20. The detector arrangement according to claim 19,
wherein the internal DC power supply line passes through the current clamp.

21. The detector arrangement according to claim 14,
wherein the sensor is further configured to detect the at least one of the DC current and voltage of the internal DC power supply line with a temporal resolution of up to 10 microseconds.

22. The detector arrangement according to claim 14,
wherein the sensor is further configured to detect the at least one of the DC current and voltage of the internal DC power supply line with a temporal resolution of up to 1 microseconds.

23. The detector arrangement according to claim 14,
wherein the detector device further comprises a sensor-power terminal configured to be connected to a third external DC power supply line; wherein the sensor-power terminal is mounted on an external face of the housing.

24. The detector arrangement according to claim 23,
wherein the third external DC power supply line is configured to supply a voltage of up to 12 V to the sensor.

25. The detector arrangement according to claim 23,
wherein the third external DC power supply line is configured to supply a voltage of up to 9 V to the sensor.

26. The detector arrangement according to claim 23, further comprising:
a first external DC power supply line, a second external DC power supply line, and a third external DC power supply line;
wherein the detector device is connected to the first external DC power supply line through the input terminal, wherein the sensor device is connected to the second external DC power supply line through the output terminal, and wherein the sensor device is connected to the third external DC power supply line through the sensor-power terminal.

27. The detector arrangement according to claim 26,
wherein any one of the first external DC power supply line or the second external DC power supply line is further connected to a plasma deposition chamber.
